(19) United States
(12) Patent Application Publication
(10) Pub. No.: US 2026/0354265 A1
(43) Pub. Date: Nov. 5, 2026

(54) SEMICONDUCTOR DEVICE AND CHIP STACKED PACKAGE HAVING BUMP

(71) Applicant: SK hynix Inc., Icheon-si Gyeonggi-do (KR)

(72) Inventors: Sung Kyu KIM, Icheon-si Gyeonggi-do (KR); Chan Ho SHIN, Icheon-si Gyeonggi-do (KR); Ju Heon YANG, Icheon-si Gyeonggi-do (KR); Myung Hyun LEE, Icheon-si Gyeonggi-do (KR)

(73) Assignee: SK hynix Inc., Icheon-si Gyeonggi-do (KR)

(21) Appl. No.: 19/350,246

(22) Filed: Oct. 6, 2025

(30) Foreign Application Priority Data
May 2, 2025 (KR) 10-2025-0057938

(51) Int. Cl. H10W 90/00; H10W 72/20; H10W 72/29; H10W 72/90; H10W 90/26

(52) U.S. Cl. CPC H10W 90/00; H10W 72/222; H10W 72/234; H10W 72/252; H10W 72/29; H10W 72/921; H10W 72/923; H10W 72/934; H10W 72/9415; H10W 72/952; H10W 90/26; H10W 90/722

(57) ABSTRACT

A semiconductor device includes a semiconductor chip, a sacrificial metal pattern, and a bump. The sacrificial metal pattern is disposed on the semiconductor chip, and the bump is disposed on the semiconductor chip and the sacrificial metal pattern. The sacrificial metal pattern includes a more anodic metal than a metal included in the bump.

### CROSS REFERENCE TO RELATED APPLICATION

The present application claims priority under 35 U.S.C. §119(a) to Korean Patent Application No. 10-2025-0057938 filed on May 2, 2025, in the Korean Intellectual Property Office, which application is incorporated herein by reference in its entirety.

### BACKGROUND

### 1. Technical Field

The present disclosure relates to semiconductor technology, including but not limited to a semiconductor device and a chip stack package including bumps.

### 2. Related Art

A chip stack package is a type of semiconductor package that improves capacity and integration by vertically stacking multiple semiconductor chips. One type of chip stack package is a through-silicon via (TSV) stack package, in which TSVs are formed in semiconductor chips, and the upper and lower semiconductor chips are electrically connected using the TSVs.

In TSV stack packages, bumps are used to connect the TSVs of the upper semiconductor chip and the lower semiconductor chip.

A TSV stack package includes a base chip, a plurality of core chips stacked on the base chip, and a mold layer encapsulating the base chip and the core chips.

### SUMMARY

According to an embodiment, a semiconductor device may include: a semiconductor chip; a sacrificial metal pattern disposed on the semiconductor chip; and a bump disposed on the semiconductor chip and the sacrificial metal pattern, wherein the sacrificial metal pattern includes a more anodic metal than a metal included in the bump.

According to an embodiment, a chip stack package may include: a first semiconductor chip; a sacrificial metal pattern disposed on the first semiconductor chip; a first bump disposed on the first semiconductor chip and the sacrificial metal pattern; a second semiconductor chip; a second bump disposed below the second semiconductor chip and connected to the first bump; and a mold layer encapsulating the first semiconductor chip, the second semiconductor chip, the first bump, the second bump, and the first sacrificial metal pattern, wherein the first sacrificial metal pattern includes a more anodic metal than a metal included in the first bump.

According to an embodiment, a chip stack package may include: a first semiconductor chip; a first bump disposed on the first semiconductor chip within a first region of the chip stack package; a second bump disposed on the first semiconductor chip within a second region surrounding the first region; a sacrificial metal pattern disposed between the first semiconductor chip and the second bump; a second semiconductor chip; a third bump disposed below the second semiconductor chip and connected to the first bump; a fourth bump disposed below the second semiconductor chip and connected to the second bump; and a mold layer encapsulating the first semiconductor chip, the second semiconductor chip, the first bump, the second bump, the third bump, the fourth bump, and the sacrificial metal pattern, wherein the sacrificial metal pattern includes a more anodic metal than a metal included in the second bump.

According to an embodiment, a chip stack package may include a first semiconductor chip and a second semiconductor chip; a first plurality of bumps disposed within a first region of the chip stack package and between the first semiconductor chip and the second semiconductor chip; a second plurality of bumps disposed within a second region surrounding the first region and between the first semiconductor chip and the second semiconductor chip; and a sacrificial metal pattern disposed on each of the second plurality of bumps; wherein the sacrificial metal pattern comprises a more anodic metal than a metal included in the second plurality of bump.

### BRIEF DESCRIPTION OF THE DRAWINGS

FIGS. 1 and 2 are cross-sectional views of semiconductor devices according to an embodiment of the present disclosure.

FIG. 3 is a cross-sectional view of a chip stack package according to an embodiment of the present disclosure.

FIG. 4 is an enlarged view of region A of FIG. 3.

FIGS. 5 and 6 are plan views illustrating first sacrificial metal patterns according to an embodiment of the present disclosure.

FIG. 7 is a plan view illustrating a first sacrificial metal pattern and a first bump according to an embodiment of the present disclosure.

FIG. 8 is a cross-sectional view showing a first sacrificial metal pattern and a first bump according to an embodiment of the present disclosure.

FIG. 9 is a plan view showing first, second, and third regions of a chip stack package according to an embodiment of the present disclosure.

FIG. 10 is a cross-sectional view of a chip stack package according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” to another element, the elements may be connected directly or through an intervening element between the elements. When two elements are identified as “directly connected,” one element is directly connected to the other element without an intervening element between the two elements.

When one element is identified as “on,” “over,” “under,” or “beneath” another element, the elements may directly contact each other or an intervening element may be disposed between the elements.

Terms such as “vertical,” “top,” ““above,” “below,” “under,” “beneath,” “overlaps,” “on,” “side,” “upper,” “lower,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

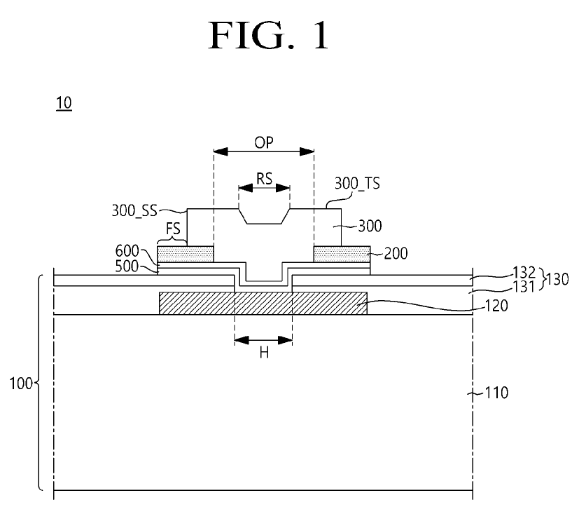

FIG. 1 is a cross-sectional view of a semiconductor device 10 according to an embodiment of the present disclosure.

Referring to FIG. 1, the semiconductor device 10 according to an embodiment of the present disclosure includes a semiconductor chip 100, a sacrificial metal pattern 200, and a bump 300.

The semiconductor chip 100 includes a chip body 110, a chip pad 120, and a protective layer 130. The chip body 110 includes an integrated circuit. The functions of the semiconductor chip 100 are implemented in the integrated circuit that includes individual elements. The chip pad 120 is disposed on an upper surface of the chip body 110 and is connected to the integrated circuit.

The protective layer 130 is disposed on the upper surface of the chip body 110. The protective layer 130 covers the upper surface of the chip body 110. A hole H is formed in the protective layer 130, through which hole H the chip pad 120 is exposed. The protective layer 130 includes a first insulating layer 131 and a second insulating layer 132. The first insulating layer 131 covers the upper surface of the chip body 110. The second insulating layer 132 is disposed on the first insulating layer 131. The first insulating layer 131 may include an oxide. The second insulating layer 132 may include a nitride. The oxide may include silicon oxide, and the nitride may include silicon nitride. In FIG. 1, the protective layer 130 is formed including two insulating layers, but is not limited to this example and may be a single insulating layer or a stacked structure including three or more insulating layers.

A base metal layer 500 is disposed on the chip pad 120 exposed through the hole H and on the protective layer 130 around the hole H. The base metal layer 500 covers the chip pad 120 and the protective layer 130 beneath the sacrificial metal pattern 200 and the bump 300. The base metal layer 500 is connected to the chip pad 120. The base metal layer 500 may include titanium.

A seed metal layer 600 is disposed on the base metal layer 500. The seed metal layer 600 is disposed between the sacrificial metal pattern 200 and the base metal layer 500 and between the bump 300 and the base metal layer 500. The seed metal layer 600 is connected to the chip pad 120 through the base metal layer 500. The seed metal layer 600 may include copper.

The sacrificial metal pattern 200 is disposed on the seed metal layer 600. An opening OP is formed in the sacrificial metal pattern 200. A section of the seed metal layer 600 is exposed through the opening OP. The opening OP vertically overlaps the chip pad 120 and the protective structure 130 around the hole H.

The sacrificial metal pattern 200 includes a more anodic metal than a metal included in the bump 300. The bump 300 may include nickel (Ni). The sacrificial metal pattern 200 may include zinc (Zn). The bump 300 may be a nickel layer. The sacrificial metal pattern 200 may be a zinc layer. The sacrificial metal pattern 200 corrodes instead of or prior to the bump 300, thereby suppressing or preventing corrosion of the bump 300. The sacrificial metal pattern 200 includes a flange FS that protrudes beyond the side surface 300_SS of the bump 300. The flange FS of the sacrificial metal pattern 200 is not covered by the bump 300 and is exposed outside the bump 300.

The bump 300 is disposed on the seed metal layer 600 exposed through the opening OP and on the sacrificial metal pattern 200 around the opening OP. The bump 300 fills the opening OP and covers the sacrificial metal pattern 200 around the opening OP. A recess RS is formed in an upper surface 300_TS of the bump 300. The recess RS vertically overlaps the opening OP. The width of the recess RS of the bump 300 is narrower than the width of the opening OP of the sacrificial metal pattern 200. The bump 300 is connected to a through electrode (not shown) via the seed metal layer 600 and the base metal layer 500.

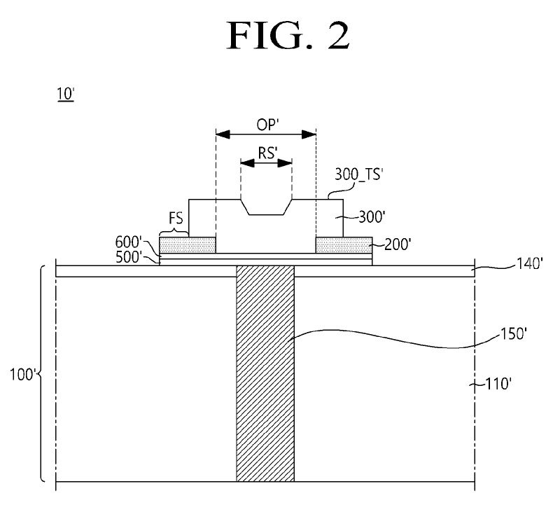

FIG. 2 is a schematic cross-sectional view of a semiconductor device 10′ according to an embodiment of the present disclosure.

Referring to FIG. 2, the semiconductor device 10′ according to an embodiment of the present disclosure includes a semiconductor chip 100′, a sacrificial metal pattern 200′, and a bump 300′.

The semiconductor chip 100′ includes a chip body 110′, a through electrode 150′, and a protective layer 140′. The chip body 110′ includes an integrated circuit. The functions of the semiconductor chip 100′ are implemented in the integrated circuit that includes individual elements.

The through electrode 150′ vertically extends through the chip body 110′. An upper end of the through electrode 150′ protrudes above the upper surface of the chip body 110′. The through electrode 150′ is connected to the integrated circuit.

The protective layer 140′ is disposed on an upper surface of the chip body 110′. The protective layer 140′ covers the upper surface of the chip body 110′. The protective layer 140′ surrounds an outer side surface of an upper end of the through electrode 150′ protruding above the upper surface of the chip body 110′. The protective layer 140′ may include an insulating material. The insulating material may include a nitride. The nitride may include silicon nitride.

A base metal layer 500′ is disposed on the semiconductor chip 100′. The base metal layer 500′ covers the through electrode 150′ and the protective layer 140′ under the sacrificial metal pattern 200′ and the bump 300′. The base metal layer 500′ is connected to the through electrode 150′. The base metal layer 500′ may include titanium.

A seed metal layer 600′ is disposed on the base metal layer 500′. The seed metal layer 600′ is disposed between the sacrificial metal pattern 200′ and the base metal layer 500′ and between the bump 300′ and the base metal layer 500′. The seed metal layer 600′ is connected to the through electrode 150′ through the base metal layer 500′. The seed metal layer 600′ may include copper.

The sacrificial metal pattern 200′ is disposed on the seed metal layer 600′. An opening OP′ is formed in the sacrificial metal pattern 200′. A section of the seed metal layer 600′ is exposed through the opening OP′. The opening OP′ vertically overlaps the through electrode 150′ and the protective layer 140′ around the through electrode 150′.

The sacrificial metal pattern 200′ includes a more anodic metal than a metal included in the bump 300′. The bump 300′ may include nickel, and the sacrificial metal pattern 200′ may include zinc. The bump 300′ may be a nickel layer or a stacked structure of a nickel layer and a gold layer, and the sacrificial metal pattern 200′ may be a zinc layer.

The sacrificial metal pattern 200′ corrodes instead of or prior to the bump 300′, thereby suppressing or preventing corrosion of the bump 300′. A flange of the sacrificial metal pattern 200′ protrudes beyond a side surface of the bump 300′. The flange of the sacrificial metal pattern 200′ is not covered by the bump 300′ and is exposed outside the bump 300′.

The bump 300′ is disposed on the seed metal layer 600′ exposed through the opening OP′ and on the sacrificial metal pattern 200′ around the opening OP′. The bump 300′ fills the opening OP′ and covers the sacrificial metal pattern 200′ around the opening OP′. The bump 300′ is connected to the through electrode 150′ through the seed metal layer 600′ and the base metal layer 500′.

A recess RS′ is formed in an upper surface 300_TS’ of the bump 300’. The recess RS′ vertically overlaps the opening OP′. The recess RS′ has a width narrower than a width of the opening OP′.

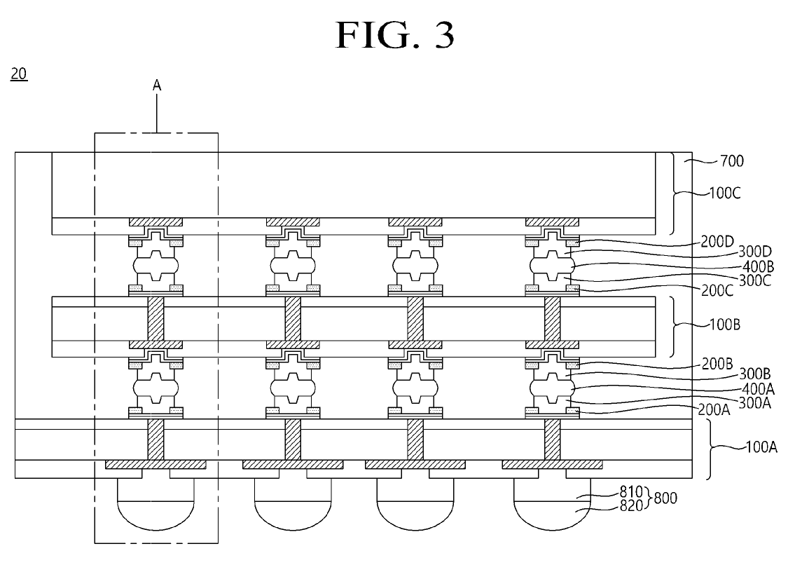

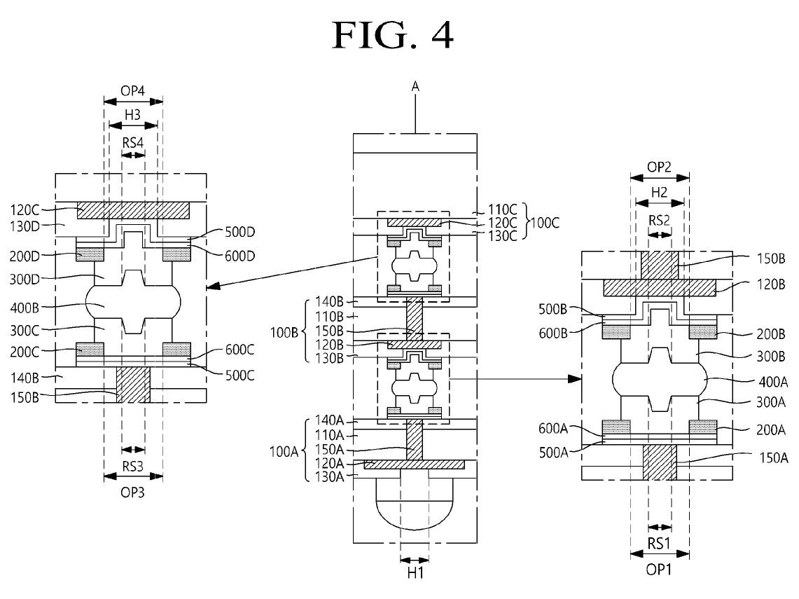

FIG. 3 is a schematic cross-sectional view of a chip stack package 20 according to an embodiment of the present disclosure, and FIG. 4 is an enlarged view of region A of FIG. 3.

Referring to FIGS. 3 and 4, the chip stack package 20 according to an embodiment of the present disclosure includes a first semiconductor chip 100A, a second semiconductor chip 100B, and a third semiconductor chip 100C; a first sacrificial metal pattern 200A, a second sacrificial metal pattern 200B, a third sacrificial metal pattern 200C, and a fourth sacrificial metal pattern 200D; and a first bump 300A, a second bump 300B, a third bump 300C, and a fourth bump 300D. The chip stack package 20 includes a first connection member 400A and a second connection member 400B; a first base metal layer 500A, a second base metal layer 500B, a third base metal layer 500C, and a fourth base metal layer 500D; a first seed metal layer 600A, a second seed metal layer 600B, a third seed metal layer 600C, and a fourth seed metal layer 600D; a mold layer 700; and an external connection member 800.

The second semiconductor chip 100B is stacked on the first semiconductor chip 100A, and the third semiconductor chip 100C is stacked on the second semiconductor chip 100B. In FIGS. 3 and 4, the number of stacked semiconductor chips is three, although the number may be two or four or more.

In an embodiment, the first semiconductor chip 100A may be a base die, the second semiconductor chip 100B may be a core middle die, and the third semiconductor chip 100C may be a core top die. Although one core middle die is illustrated in FIGS. 3 and 4, two or more core middle dies may be stacked between the base die and the core top die.

The first semiconductor chip 100A includes a first chip body 110A, a first chip pad 120A, a first lower protective layer 130A, a first upper protective layer 140A, and a first through electrode 150A.

The first chip body 110A includes a first integrated circuit. The first integrated circuit may be implemented in various ways depending on the type of the first semiconductor chip 100A. In one embodiment, the semiconductor chips 100B and 100C may be memory dies, and the semiconductor chip 100A may be a logic die that controls the memory dies. The first integrated circuit includes individual elements that control the memory dies.

The first chip pad 120A is disposed under a lower surface of the first chip body 110A. The first chip pad 120A is connected to the first integrated circuit. The first lower protective layer 130A is disposed under the lower surface of the first chip body 110A. The first lower protective layer 130A covers the lower surface of the first chip body 110A. A first hole H1 is formed in the first lower protective layer 130A, through which first hole H1 the first chip pad 120A is exposed. The first lower protective layer 130A includes an insulating material. The insulating material may include an oxide and/or a nitride.

The first through electrode 150A vertically extends through the first chip body 110A. A lower end of the first through electrode 150A is exposed through the lower surface of the first chip body 110A. The lower end of the first through electrode 150A is connected to the first chip pad 120A. An upper end of the first through electrode 150A protrudes above the upper surface of the first chip body 110A.

The first upper protective layer 140A is disposed on the upper surface of the first chip body 110A. The first upper protective layer 140A covers the upper surface of the first chip body 110A. The first upper protective layer 140A surrounds an outer side surface of the upper end of the first through electrode 150A protruding above the upper surface of the first chip body 110A. The first upper protective layer 140A may include an insulating material. The insulating material may include a nitride.

A first base metal layer 500A is disposed on the first semiconductor chip 100A. The first base metal layer 500A covers the first through electrode 150A and the first upper protective layer 140A under the first sacrificial metal pattern 200A and the first bump 300A. The first base metal layer 500A is connected to the first through electrode 150A. The first base metal layer 500A may include titanium.

A first seed metal layer 600A is disposed on the first base metal layer 500A. The first seed metal layer 600A is disposed between the first sacrificial metal pattern 200A and the first base metal layer 500A, and between the first bump 300A and the first base metal layer 500A. The first seed metal layer 600A is connected to the first through electrode 150A through the first base metal layer 500A. The first seed metal layer 600A may include copper.

The first sacrificial metal pattern 200A is disposed on the first seed metal layer 600A. A first opening OP1 is formed in the first sacrificial metal pattern 200A. A section of the first seed metal layer 600A is exposed through the first opening OP1. The first opening OP1 vertically overlaps the first through electrode 150A and the first upper protective layer 140A around the first through electrode 150A.

The first sacrificial metal pattern 200A includes a more anodic metal than a metal included in the first bump 300A. The first bump 300A may include nickel, and the first sacrificial metal pattern 200A may include zinc. The first bump 300A may be a nickel layer or a stacked structure of a nickel layer and a gold layer, and the first sacrificial metal pattern 200A may be a zinc layer. The first sacrificial metal pattern 200A corrodes instead of or prior to the first bump 300A, thereby suppressing or preventing corrosion of the first bump 300A. A flange of the first sacrificial metal pattern 200A protrudes beyond a side surface of the first bump 300A. The flange of the first sacrificial metal pattern 200A is not covered by the first bump 300A and is exposed outside the first bump 300A.

The first bump 300A is disposed on the first seed metal layer 600A exposed through the first opening OP1 and on the first sacrificial metal pattern 200A around the first opening OP1. The first bump 300A fills the first opening OP1 and covers the first sacrificial metal pattern 200A around the first opening OP1. A first recess RS1 is formed in an upper surface of the first bump 300A. The first recess RS1 vertically overlaps the first opening OP1 of the first sacrificial metal pattern 200A. The first recess RS1 has a width narrower than a width of the first opening OP1.

A first dummy bump (not shown) may be disposed on the first semiconductor chip 100A. The first dummy bump may be formed during a process of forming the first bump 300A. The first dummy bump may support the second semiconductor chip 100B to relieve stress on the first bump 300A. The first dummy bump may not be used to input and/or output electrical signals. No electrical signal may be applied to the first dummy bump. The first dummy bump may be electrically floating.

A sacrificial metal pattern may not be disposed between the first dummy bump and the first semiconductor chip 100A. Because no electrical signal is applied to a dummy bump, corrosion of the first dummy bump does not cause electrical failure, thus a sacrificial metal pattern is not included on the dummy bump.

The second semiconductor chip 100B includes a second chip body 110B, a second chip pad 120B, a second lower protective layer 130B, a second upper protective layer 140B, and a second through electrode 150B.

The second chip body 110B includes a second integrated circuit. The second integrated circuit may be implemented in various ways depending on the type of the second semiconductor chip 100B. In an embodiment, the second semiconductor chip 100B is a memory die, and the second integrated circuit includes memory cells.

The second chip pad 120B is disposed under a lower surface of the second chip body 110B. The second chip pad 120B is electrically connected to the second integrated circuit. The second lower protective layer 130B is disposed under the lower surface of the second chip body 110B. The second lower protective layer 130B covers the lower surface of the second chip body 110B. A second hole H2 is formed in the second lower protective layer 130B through which second hole H2 the second chip pad 120B is exposed. The second lower protective layer 130B includes an insulating material. The insulating material may include an oxide and/or a nitride.

The second through electrode 150B vertically extends through the second chip body 110B. A lower end of the second through electrode 150B is exposed through the lower surface of the second chip body 110B. A lower end of the second through electrode 150B is connected to the second chip pad 120B. An upper end of the second through electrode 150B protrudes above the upper surface of the second chip body 110B.

The second upper protective layer 140B is disposed on the upper surface of the second chip body 110B. The second upper protective layer 140B covers the upper surface of the second chip body 110B. The second upper protective layer 140B surrounds an outer side surface of the upper end of the second through electrode 150B protruding above the upper surface of the second chip body 110B. The second upper protective layer 140B may include an insulating material. The insulating material may include a nitride.

The second base metal layer 500B is disposed under the second chip pad 110B exposed through the second hole H2 and the second lower protective layer 130B around the second hole H2. The second base metal layer 500B is disposed above the second sacrificial metal pattern 200B and the second bump 300B to cover the second chip pad 120B and the second lower protective layer 130B. The second base metal layer 500B is connected to the second chip pad 120B. The second base metal layer 500B may include titanium.

The second seed metal layer 600B is disposed under the second base metal layer 500B. The second seed metal layer 600B is disposed between the second sacrificial metal pattern 200B and the second base metal layer 500B and between the second bump 300B and the second base metal layer 500B. The second seed metal layer 600B is connected to the second chip pad 120B through the second base metal layer 500B. The second seed metal layer 600B may include copper.

The second sacrificial metal pattern 200B is disposed under the second seed metal layer 600B. A second opening OP2 is formed in the second sacrificial metal pattern 200B. A section of the second seed metal layer 600B is exposed through the second opening OP2. The second opening OP2 vertically overlaps the second chip pad 120B exposed through the second hole H2 and the second lower protective layer 130B around the second hole H2.

The second sacrificial metal pattern 200B includes a more anodic metal than a metal included in the second bump 300B. The second bump 300B may include nickel, and the second sacrificial metal pattern 200B may include zinc. The second bump 300B may be a nickel layer, and the second sacrificial metal pattern 200B may be a zinc layer. The second sacrificial metal pattern 200B corrodes instead of or prior to the second bump 300B, thereby suppressing or preventing corrosion of the second bump 300B. A flange of the second sacrificial metal pattern 200B protrudes beyond a side surface of the second bump 300B. The flange of the second sacrificial metal pattern 200B is not covered by the second bump 300B and is exposed outside the second bump 300B.

The second bump 300B is disposed under the second seed metal layer 600B exposed through the second opening OP2 and the second sacrificial metal pattern 200B. The second bump 300B fills the second opening OP2 and covers the second sacrificial metal pattern 200B around the second opening OP2. A second recess RS2 is formed in a lower surface of the second bump 300B. The second recess RS2 vertically overlaps the second opening OP2. The second recess RS2 has a width narrower than a width of the second opening OP2. The second bump 300B is connected to the second chip pad 120B through the second seed metal layer 600B and the second base metal layer 500B.

A first connection member 400A is disposed under the second bump 300B. The first connection member 400A may be a solder layer. The solder layer may include tin (Sn) or a tin-silver (Sn-Ag) alloy.

The first connection member 400A is bonded to the first bump 300A. The bonding process may include: applying flux to the first connection member 400A; temporarily attaching the first connection member 400A to the first bump 300A; removing the flux; and fastening the first connection member 400A to the first bump 300A through a reflow and cooling process. The second bump 300B is connected to the first bump 300A through the first connection member 400A.

A second dummy bump (not shown) may be disposed under the second semiconductor chip 100B. The second dummy bump may be formed during a process of forming the second bump 300B. The second dummy bump may support the second semiconductor chip 100B to relieve stress on the second bump 300B. The second dummy bump may not be used to input and/or output electrical signals. No electrical signal may be applied to the second dummy bump. The second dummy bump may be electrically floating.

A sacrificial metal pattern may not be disposed between the second dummy bump and the second semiconductor chip 100B. Because no electrical signal is applied to a dummy bump, corrosion of the second dummy bump does not cause electrical failure, thus a sacrificial metal pattern is not included on the dummy bump.

A third base metal layer 500C is disposed on the second semiconductor chip 100B. The third base metal layer 500C is disposed beneath the third sacrificial metal pattern 200C and the third bump 300C and covers the second upper protective layer 140B and the second through electrode 150B. The third base metal layer 500C is connected to the second through electrode 150B. The third base metal layer 500C may include titanium.

A third seed metal layer 600C is disposed on the third base metal layer 500C. The third seed metal layer 600C is disposed between the third sacrificial metal pattern 200C and the third base metal layer 500C and between the third bump 300C and the third base metal layer 500C. The third seed metal layer 600C is connected to the second through electrode 150B through the third base metal layer 500C. The third seed metal layer 600C may include copper.

The third sacrificial metal pattern 200C is disposed on the third seed metal layer 600C. A third opening OP3 is formed in the third sacrificial metal pattern 200C. A section of the third seed metal layer 600C is exposed through the third opening OP3. The third opening OP3 vertically overlaps the second through electrode 150B and the second upper protective layer 140B around the second through electrode 150B.

The third sacrificial metal pattern 200C includes a more anodic metal than a metal included in the third bump 300C. The third bump 300C may include nickel, and the third sacrificial metal pattern 200C may include zinc. The third bump 300C may be a nickel layer or a stacked structure of a nickel layer and a gold layer, and the third sacrificial metal pattern 200C may be a zinc layer. The third sacrificial metal pattern 200C corrodes instead of or prior to the third bump 300C, thereby suppressing or preventing corrosion of the third bump 300C. A flange of the third sacrificial metal pattern 200C protrudes beyond a side surface of the third bump 300C. The flange of the third sacrificial metal pattern 200C is not covered by the third bump 300C and is exposed outside the third bump 300C.

The third bump 300C is disposed on the third seed metal layer 600C exposed through the third opening OP3 and on the third sacrificial metal pattern 200C around the third opening OP3. The third bump 300C fills the third opening OP3 and covers the third sacrificial metal pattern 200C around the third opening OP3. The third bump 300C is connected to the second through electrode 150B through the third seed metal layer 600C and the third base metal layer 500C.

A third recess RS3 is formed in an upper surface of the third bump 300C. The third recess RS3 vertically overlaps the third opening OP3 of the third sacrificial metal pattern 200C. The third recess RS3 has a width narrower than a width of the third opening OP3.

A third dummy bump (not shown) may be disposed on the second semiconductor chip 100B. The third dummy bump may be formed during a process of forming the third bump 300C. The third dummy bump may support the third semiconductor chip 100C to relieve stress on the third bump 300C. The third dummy bump may not be used to input and/or output electrical signals. No electrical signal may be applied to the third dummy bump. The third dummy bump may be electrically floating.

A sacrificial metal pattern may not be disposed between the third dummy bump and the second semiconductor chip 100B. Because no electrical signal is applied to a dummy bump, corrosion of the third dummy bump does not cause an electrical failure. Accordingly, a sacrificial metal pattern is not included on the third dummy bump.

The third semiconductor chip 100C includes a third chip body 110C, a third chip pad 120C, and a third lower protective layer 130C.

The third chip body 110C includes a third integrated circuit. The third integrated circuit may be implemented in various ways depending on the type of the third semiconductor chip 100C. In an embodiment, the third semiconductor chip 100C may be a memory die, and the third integrated circuit may include memory cells. The third chip body 110C may have a different thickness than the thickness of the second chip body 110B. The third chip body 110C may be thicker than the second chip body 110B.

The third chip pad 120C is disposed under a lower surface of the third chip body 110C. The third chip pad 120C is connected to the third integrated circuit. The third lower protective layer 130C is disposed under the lower surface of the third chip body 110C. The third lower protective layer 130C covers the lower surface of the third chip body 110C. A third hole H3 is formed in the third lower protective layer 130C, through which third hole H3 the third chip pad 120C is exposed. The third lower protective layer 130C includes an insulating material. The insulating material may include an oxide and/or a nitride.

The fourth base metal layer 500D is disposed below the third chip pad 120C exposed through a fourth hole H4 and the third lower protective layer 130C around the fourth hole H4. The fourth base metal layer 500D covers the third chip pad 120C and the third lower protective layer 130C from above the fourth sacrificial metal pattern 200D and the fourth bump 300D. The fourth base metal layer 500D may include titanium. The fourth base metal layer 500D is connected to the third chip pad 120C.

A fourth seed metal layer 600D is disposed under the fourth base metal layer 500D. The fourth seed metal layer 600D is disposed between the fourth sacrificial metal pattern 200D and the fourth base metal layer 500D and between the fourth bump 300D and the fourth base metal layer 500D. The fourth seed metal layer 600D is connected to the third chip pad 120C through the fourth base metal layer 500D. The fourth seed metal layer 600D may include copper.

The fourth sacrificial metal pattern 200D is disposed under the fourth seed metal layer 600D. A fourth opening OP4 is formed in the fourth sacrificial metal pattern 200D. A section of the fourth seed metal layer 600D is exposed through the fourth opening OP4. The fourth opening OP4 vertically overlaps the third chip pad 120C exposed through the third hole H3 and the third lower protective layer 130C around the third hole H3.

The fourth sacrificial metal pattern 200D includes a more anodic metal than a metal included in the fourth bump 300D. The fourth bump 300D may include nickel, and the fourth sacrificial metal pattern 200D may include zinc. The fourth bump 300D may be a nickel layer, and the fourth sacrificial metal pattern 200D may be a zinc layer. The fourth sacrificial metal pattern 200D corrodes instead of or prior to the fourth bump 300D, thereby suppressing or preventing corrosion of the fourth bump 300D. A flange of the fourth sacrificial metal pattern 200D protrudes beyond a side surface of the fourth bump 300D. The flange of the fourth sacrificial metal pattern 200D is not covered by the fourth bump 300D and is exposed outside the fourth bump 300D.

The fourth bump 300D is disposed under the fourth seed metal layer 600D exposed through the fourth opening OP4 and under the fourth sacrificial metal pattern 200D. The fourth bump 300D fills the fourth opening OP4 and covers the fourth sacrificial metal pattern 200D around the fourth opening OP4. A fourth recess RS4 is formed in a lower surface of the fourth bump 300D. The fourth recess RS4 vertically overlaps the fourth opening OP4. The fourth recess RS4 has a width narrower than a width of the fourth opening OP4. The fourth bump 300D is connected to the third chip pad 120C through the fourth seed metal layer 600D and the fourth base metal layer 500D.

A fourth dummy bump (not shown) may be disposed under the third semiconductor chip 100C. The fourth dummy bump may be formed during a process of forming the fourth bump 300D. The fourth dummy bump may support the third semiconductor chip 100C to relieve stress on the fourth bump 300D. The fourth dummy bump may not be used to input and/or output electrical signals. No electrical signal may be applied to the fourth dummy bump. The fourth dummy bump may be electrically floating.

A sacrificial metal pattern may not be disposed between the fourth dummy bump and the third semiconductor chip 100C. Because no electrical signal is applied to a dummy bump, corrosion of the fourth dummy bump does not cause electrical failure. Accordingly, a sacrificial metal pattern is not included on the fourth dummy bump.

A second connection member 400B is disposed under the fourth bump 300D. The second connection member 400B may be a solder layer. The solder layer may include tin (Sn) or a tin-silver (Sn-Ag) alloy.

The second connection member 400B is bonded to the third bump 300C. The bonding process may include: applying flux to the second connection member 400B; temporarily attaching the second connection member 400B onto the third bump 300C; removing the flux; and fastening the second connection member 400B to the third bump 300C through a reflow and cooling process. The fourth bump 300D is connected to the third bump 300C through the second connection member 400B.

A mold layer 700 encapsulates the semiconductor chips 100A, 100B, and 100C, the sacrificial metal patterns 200A, 200B, 200C, and 200D, and the bumps 300A, 300B, 300C, and 300D. The mold layer 700 encapsulates these components to protect the components from the external environment.

The mold layer 700 is disposed on the first semiconductor chip 100A and covers side surfaces of the semiconductor chips 100B and 100C. The upper surface of the third semiconductor chip 100C is exposed through the mold layer 700. The upper surface of the mold layer 700 may be in the same plane as the upper surface of the third semiconductor chip 100C. Because the upper surface of the third semiconductor chip 100C is not covered by the mold layer 700, heat generated during operation of the semiconductor chips 100A, 100B, and 100C may be released outside the chip stack package 20 through the upper surface of the third semiconductor chip 100C without interference from the mold layer 700.

The mold layer 700 extends to fill spaces between the semiconductor chips 100A, 100B, and 100C. The mold layer 700 may have a molded underfill (MUF) structure that fills the spaces between the semiconductor chips 100A, 100B, and 100C. In another example, the spaces between the semiconductor chips 100A, 100B, and 100C may be filled with a separate underfill material different from the mold layer 700. In another example, adhesive layers may be disposed between the first semiconductor chip 100A and the second semiconductor chip 100B and between the second semiconductor chip 100B and the third semiconductor chip 100C, thereby attaching the semiconductor chips 100A, 100B, and 100C.

The mold layer 700 may be formed by a molding process using a liquid encapsulating material. The encapsulating material may include an epoxy molding compound (EMC).

The external connection member 800 is disposed under the first semiconductor chip 100A. The external connection member 800 is disposed under the first chip pad 120A exposed through the first hole H1 and the first lower protective layer 130A around the first chip pad 120A. The external connection member 800 is connected to the first chip pad 120A. The external connection member 800 includes a metal pillar 810 and a solder layer 820 under the metal pillar 810. The metal pillar 810 may include copper. The solder layer 820 may include tin or a tin-silver alloy.

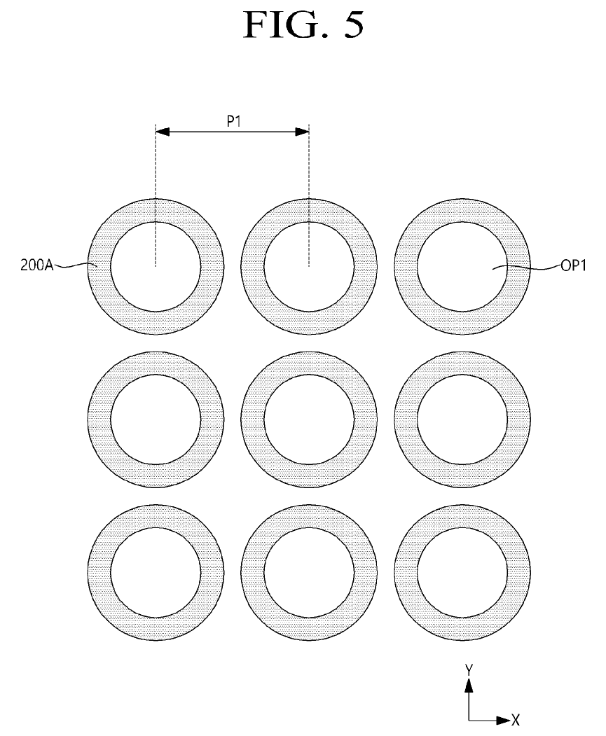

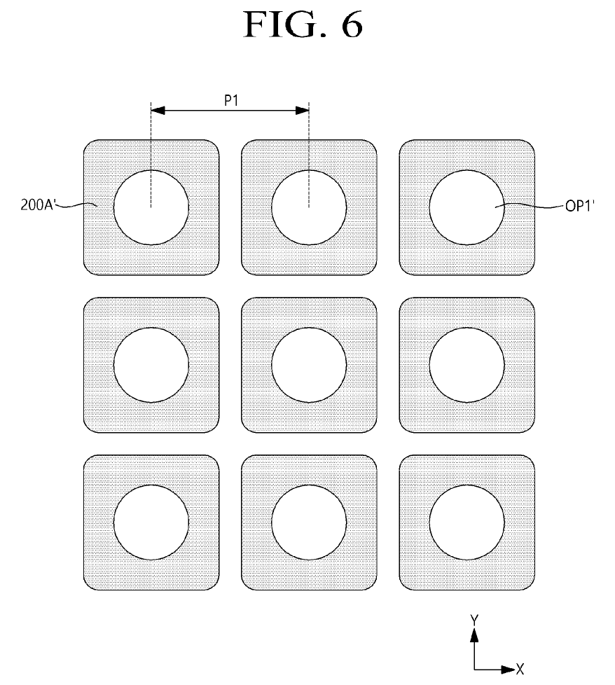

FIGS. 5 and 6 are plan views illustrating first sacrificial metal patterns according to embodiments of the present disclosure.

Referring to FIG. 5, a plurality of first sacrificial metal patterns 200A are arranged along the X direction and the Y direction. The first sacrificial metal patterns 200A are repeatedly arranged along the X direction and the Y direction according to a first pitch P1. The first sacrificial metal pattern 200A has a ring structure or an annular structure with a first opening OP1 formed at a center of the first sacrificial metal pattern 200A.

Referring to FIG. 6, the first sacrificial metal pattern 200A' has a rectangular frame structure with a first opening OP1' formed at a center of the first sacrificial metal pattern 200A’. When the first sacrificial metal pattern 200A' is configured as a rectangular frame structure, the first sacrificial metal pattern 200A' has a larger planar area and greater volume than the first sacrificial metal pattern 200A of FIG. 5.

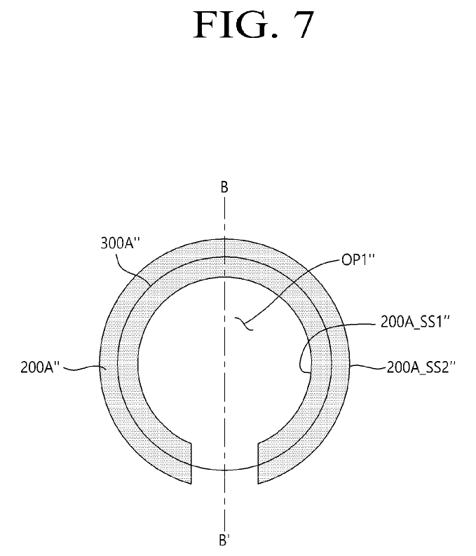

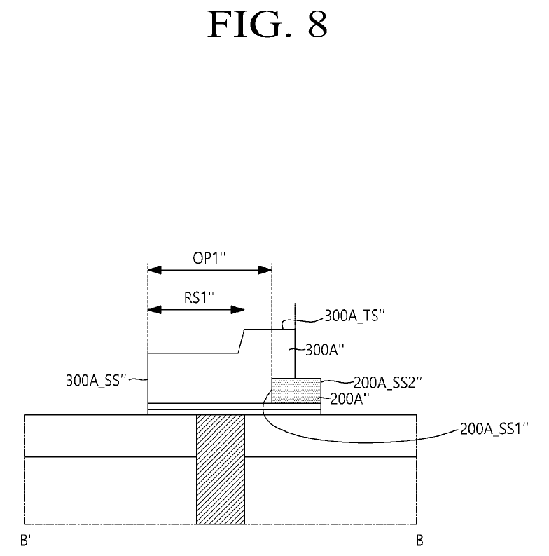

FIG. 7 is a plan view illustrating the first sacrificial metal pattern and the first bump according to an embodiment of the present disclosure, and FIG. 8 is a cross-sectional view illustrating the first sacrificial metal pattern and the first bump according to an embodiment of the present disclosure. FIG. 8 shows a cross-sectional view taken along line B-B' in FIG. 7.

Referring to FIGS. 7 and 8, the first sacrificial metal pattern 200A'' has an inner surface 200A_SS1'' exposed through the first opening OP1'' and an outer surface 200A_SS2''. The first opening OP1'' is open to the outer surface 200A_SS2'' of the first sacrificial metal pattern 200A''. The first sacrificial metal pattern 200A'' has an open ring structure or a partial ring structure.

A first recess RS1'' is formed on an upper surface 300A_TS'' of the first bump 300A'' and vertically overlaps with the first opening OP1''. The first recess RS1'' is open to a side surface 300A_SS'' of the first bump 300A''. Because the first recess RS1'' is open to the side surface 300A_SS'' of the first bump 300A'', flux applied to the first connection member (400A in FIG. 3) during a process of temporarily attaching the first connection member 400A to the first bump 300A″ flows to the side surface 300A_SS” of the first bump 300A'' through the first recess RS1''. Accordingly, trapping and residual retention of flux on the upper surface 300A_TS'' of the first bump 300A″ may be suppressed or prevented, and formation of voids caused by the residual flux may also be suppressed or prevented.

The description of the first sacrificial metal pattern with reference to FIGS. 5-8 applies to the sacrificial metal patterns 200B, 200C, and 200D in FIG. 3. The description of the first bump with reference to FIGS. 5-8 applies to the bumps 300B, 300C, and 300D in FIG. 3.

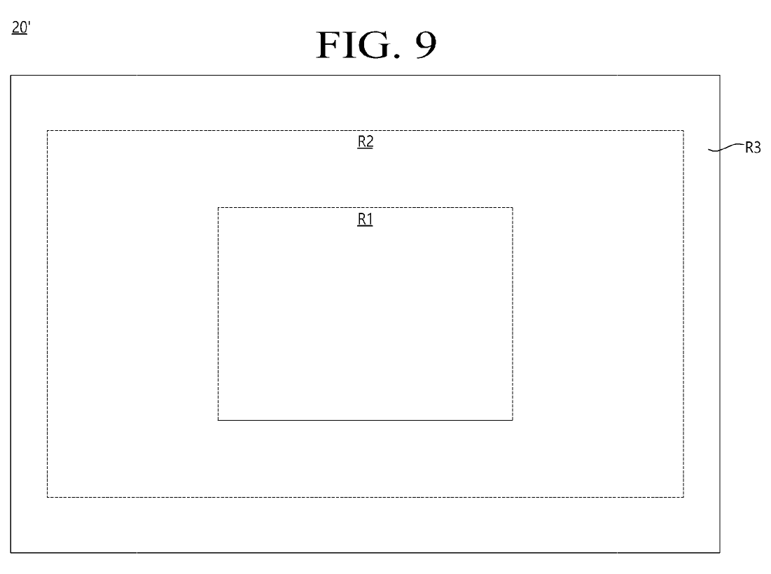

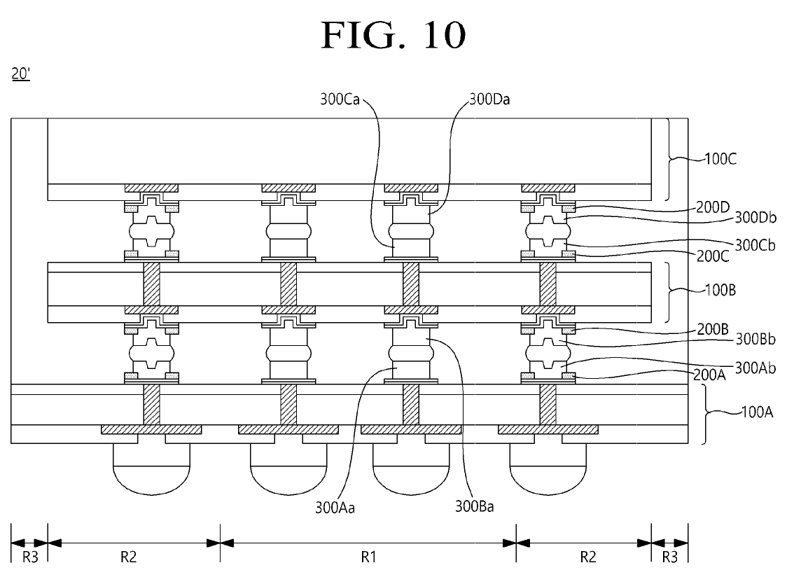

FIG. 9 is a plan view illustrating regions of a chip stack package 20' according to an embodiment of the present disclosure, and FIG. 10 is a cross-sectional view of the chip stack package 20' through a first region R1 of FIG. 9.

Referring to FIGS. 9 and 10, the chip stack package 20' includes the first region R1, a second region R2, and a third region R3.

The second region R2 surrounds an edge of the first region R1, and the third region R3 surrounds an edge of the second region R2. The second region R2 is disposed between the first region R1 and the third region R3.

The first semiconductor chip 100A and the mold layer 700 are disposed in the first region R1, the second region R2, and the third region R3. The semiconductor chips 100B and 100C are disposed in the first region R1 and the second region R2.

First bumps 300Aa and 300Ab include a first center bump 300Aa disposed in the first region R1 and a first edge bump 300Ab disposed in the second region R2. The first sacrificial metal pattern 200A is disposed between the first edge bump 300Ab and the first semiconductor chip 100A. No sacrificial metal pattern is disposed between the first center bump 300Aa and the first semiconductor chip 100A.

Second bumps 300Ba and 300Bb include a second center bump 300Ba disposed in the first region R1 and a second edge bump 300Bb disposed in the second region R2. The second sacrificial metal pattern 200B is disposed between the second edge bump 300Bb and the second semiconductor chip 100B. No sacrificial metal pattern is disposed between the second center bump 300Ba and the second semiconductor chip 100B.

Third bumps 300Ca and 300Cb include a third center bump 300Ca disposed in the first region R1 and a third edge bump 300Cb disposed in the second region R2. The third sacrificial metal pattern 200C is disposed between the third edge bump 300Cb and the second semiconductor chip 100B. No sacrificial metal pattern is disposed between the third center bump 300Ca and the second semiconductor chip 100B.

Fourth bumps 300Da and 300Db include a fourth center bump 300Da disposed in the first region R1 and a fourth edge bump 300Db disposed in the second region R2. The fourth sacrificial metal pattern 200D is disposed between the fourth edge bump 300Db and the third semiconductor chip 100C. No sacrificial metal pattern is disposed between the fourth center bump 300Da and the third semiconductor chip 100C.

Moisture may penetrate the chip stack package 20' from the outside through the mold layer 700. Therefore, the edge bumps 300Ab, 300Bb, 300Cb, and 300Db disposed in the second region R2 are more likely to be corroded than the center bumps 300Aa, 300Ba, 300Ca, and 300Da disposed in the first region R1. In this example, sacrificial metal patterns are included for the edge bumps 300Ab, 300Bb, 300Cb, and 300Db that are more likely to corrode and not included for the center bumps 300Aa, 300Ba, 300Ca, and 300Da that are less likely to corrode. Thus, a first plurality of bumps of the chip stack package 20’ is formed with a sacrificial metal pattern, and a second plurality of bumps of the chip stack package 20’ is formed without a sacrificial metal pattern. The first plurality of bumps is disposed around the second plurality of bumps.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a semiconductor chip;
a sacrificial metal pattern disposed on the semiconductor chip; and
a bump disposed on the semiconductor chip and the sacrificial metal pattern;
wherein the sacrificial metal pattern comprises a more anodic metal than a metal included in the bump.

2. The semiconductor device according to claim 1, wherein the bump comprises nickel (Ni), and the sacrificial metal pattern comprises zinc (Zn).

3. The semiconductor device according to claim 1,
wherein an opening is formed in the sacrificial metal pattern; and
wherein the bump fills the opening formed in the sacrificial metal pattern and covers the sacrificial metal pattern around the opening.

4. The semiconductor device according to claim 3, wherein the opening formed in the sacrificial metal pattern is open to an outer surface of the sacrificial metal pattern.

5. The semiconductor device according to claim 3, wherein a recess is formed in an upper surface of the bump, the recess vertically overlapping the opening formed in the sacrificial metal pattern.

6. The semiconductor device according to claim 5, wherein the recess formed in the bump has a width narrower than a width of the opening formed in the sacrificial metal pattern.

7. The semiconductor device according to claim 5, wherein the recess formed in the bump is open to a side surface of the bump.

8. The semiconductor device according to claim 1, wherein a flange of the sacrificial metal pattern protrudes beyond a side surface of the bump.

9. The semiconductor device according to claim 1, further comprising:
a base metal layer disposed under the bump and the sacrificial metal pattern to cover the semiconductor chip; and
a seed metal layer disposed between the sacrificial metal pattern and the base metal layer and between the bump and the base metal layer.

10. The semiconductor device according to claim 9, wherein the seed metal layer comprises copper, and the base metal layer comprises titanium.

11. A chip stack package comprising:
a first semiconductor chip;
a sacrificial metal pattern disposed on the first semiconductor chip;
a first bump disposed on the first semiconductor chip and the sacrificial metal pattern;
a second semiconductor chip;
a second bump disposed under the second semiconductor chip and connected to the first bump; and
a mold layer encapsulating the first semiconductor chip, the second semiconductor chip, the first bump, the second bump, and the sacrificial metal pattern;
wherein the sacrificial metal pattern comprises a more anodic metal than a metal included in the first bump.

12. The chip stack package according to claim 11, further comprising a second sacrificial metal pattern disposed between the second semiconductor chip and the second bump; and
wherein the second sacrificial metal pattern comprises a more anodic metal than a metal included in the second bump.

13. The chip stack package according to claim 11,
wherein an opening is formed in the sacrificial metal pattern; and
wherein the first bump fills the opening formed in the sacrificial metal pattern and covers the first sacrificial metal pattern around the opening.

14. The chip stack package according to claim 13, wherein the opening formed in the sacrificial metal pattern is open to an outer surface of the sacrificial metal pattern.

15. The chip stack package according to claim 13, wherein a recess is formed in an upper surface of the bump, the recess vertically overlapping the opening formed in the sacrificial metal pattern.

16. The chip stack package according to claim 15, wherein the recess formed the first bump has a width narrower than a width of the opening formed in the sacrificial metal pattern.

17. The chip stack package according to claim 15, wherein the recess formed in the first bump is open to a side surface of the first bump.

18. The chip stack package according to claim 11, wherein a flange of the sacrificial metal pattern protrudes beyond a side surface of the first bump.

19. A chip stack package comprising:
a first semiconductor chip and a second semiconductor chip;
a first plurality of bumps disposed within a first region of the chip stack package and between the first semiconductor chip and the second semiconductor chip;
a second plurality of bumps disposed within a second region surrounding the first region and between the first semiconductor chip and the second semiconductor chip; and
a sacrificial metal pattern disposed on each of the second plurality of bumps;
wherein the sacrificial metal pattern comprises a more anodic metal than a metal included in the second plurality of bump.

20. The chip stack package of claim 19, wherein the first plurality of bumps are formed without a sacrificial metal pattern thereon.
